(19) United States
(12) Patent Application Publication
(10) Pub. No.: US 2021/0043766 A1
(43) Pub. Date: Feb. 11, 2021

(54) STRUCTURE WITH COUNTER DOPING REGION BETWEEN N AND P WELLS UNDER GATE STRUCTURE

(71) Applicant: GLOBALFOUNDRIES INC., Grand Cayman (KY)

(72) Inventors: Baofu Zhu, Clifton Park, NY (US); Shesh Mani Pandey, Saratoga Springs, NY (US); Jiehui Shu, Clifton Park, NY (US); Sipeng Gu, Clifton Park, NY (US); Haiting Wang, Clifton Park, NY (US)

(21) Appl. No.: 16/533,835

(22) Filed: Aug. 7, 2019

(51) Int. Cl. H01L 29/78; H01L 29/66

(52) U.S. Cl. CPC H01L 29/7816; H01L 29/66681

(57) ABSTRACT

A laterally diffused metal-oxide semiconductor (LDMOS) device is disclosed. The LDMOS FET includes a gate structure between a source region and a drain region over a p-type semiconductor substrate; and a trench isolation partially under the gate structure and between the gate structure and the drain region. A p-well is under and adjacent the source region; and an n-well is under and adjacent the drain region. A counter doping region abuts and is between the p-well and the n-well, and is directly underneath the gate structure. The counter doping region increases drain-source breakdown voltage compares to conventional approaches.

### BACKGROUND

The present disclosure relates to integrated circuits (IC), and more specifically, to a structure with a counter doping region between N and P wells under a gate structure to, for example, improve drain-source breakdown voltage.

Laterally diffused metal-oxide semiconductor (LDMOS) field effect transistors (FETs) are used in a variety of integrated circuit applications such as microwave or radio frequency (RF) power amplifiers. An LDMOS FET is an asymmetric power FET designed for low resistance and high drain-source breakdown voltage. These devices use a diffused p-type channel region in a low-doped n-type drain region. Continuing manufacture and operability of LDMOS FETs at advanced technology nodes, e.g., 14 nanometers and beyond, present numerous challenges. One challenge is providing a sufficient drain-source breakdown voltage (BVdss) to ensure operability of the devices. Drain-source breakdown voltage is the drain-to-source voltage at which no more than a particular drain current will flow at a particular temperature with no gate-source voltage. The drain-source breakdown voltage is generally aligned with the actual device breakdown voltage. Typically, drain-source breakdown voltage increases with channel length (i.e., the distance between the drain and source) up to a certain maximum length, e.g., 300 nm at the 14 nm technology node. Most approaches to increase drain-source breakdown voltage in LDMOS FETs thus attempt to lengthen the distance current must travel between the drain and source. FIG. 1 shows a conventional LDMOS 8 including a p-type semiconductor substrate 10 with a p-well 12 and an abutting n-well 14. A gate structure 16 is over a gate dielectric 18. One current approach to increase drain-source breakdown voltage includes placing a shallow trench isolation (STI) 20 between a source region 22 and a drain region 24, which causes the current to have to pass around STI 20 when gate structure 16 activates a channel region 26. However, this approach is insufficient to provide the necessary breakdown voltage for, for example, current RF devices at advanced technology nodes.

### SUMMARY

A first aspect of the disclosure is directed to a structure comprising: a gate structure between a first doping region and a second doping region over a substrate; a trench isolation partially under the gate structure and between the gate structure and the second doping region; a first well under and adjacent the first doping region; a second well under and adjacent the second doping region; and a counter doping region abutting and between the first well and the second well, the counter doping region directly underneath the gate structure.

A second aspect of the disclosure includes a method, comprising: forming a trench isolation in a semiconductor substrate; forming a first mask over the semiconductor substrate, the first mask exposing a first region to a first side of and distanced from the trench isolation; using the first mask, forming a first well in the semiconductor substrate in the first region, the first well distanced from the trench isolation; removing the first mask; forming a second mask over the semiconductor substrate, the second mask exposing a second region including a portion of a width of the first well; using the second mask, form a second well in the semiconductor substrate in the second region and a counter doping region in the portion of the width of the first well, the first well and the second well having different dopant types; removing the second mask; forming a first doping region in the first well and a second doping region in the second well on an opposite side of the trench isolation from the first well; and forming a gate structure between the first doping region and the second doping region over the semiconductor substrate.

A third aspect of the disclosure related to a laterally diffused metal-oxide semiconductor (LDMOS) field effect transistor (FET), comprising: a gate structure between a source region and a drain region over a p-type semiconductor substrate; a trench isolation partially under the gate structure and between the gate structure and the drain region; a p-well under and adjacent the source region; an n-well under and adjacent the drain region; and a counter doping region abutting and between the p-well and the n-well, the counter doping region directly underneath the gate structure.

The foregoing and other features of the disclosure will be apparent from the following more particular description of embodiments of the disclosure.

### BRIEF DESCRIPTION OF THE DRAWINGS

The embodiments of this disclosure will be described in detail, with reference to the following figures, wherein like designations denote like elements, and wherein:

FIG. 1 shows a cross-sectional view of a conventional laterally diffused metal-oxide semiconductor device.

FIG. 2 shows a cross-sectional view of forming a trench isolation in a semiconductor substrate, according to embodiments of the disclosure.

FIG. 3 shows a cross-sectional view of a step of forming a first well superimposed above a cross-sectional view of a step of forming a second well and a counter doping region, according to embodiments of the disclosure.

FIG. 4 shows a cross-sectional view of forming a first and second doping regions (source/drain regions), according to embodiments of the disclosure.

FIG. 5 shows a cross-sectional view of forming a gate structure according to embodiments of the disclosure, and a structure and an LDMOS FET according to embodiments of the disclosure.

It is noted that the drawings of the disclosure are not necessarily to scale. The drawings are intended to depict only typical aspects of the disclosure, and therefore should not be considered as limiting the scope of the disclosure. In the drawings, like numbering represents like elements between the drawings.

### DETAILED DESCRIPTION

Embodiments of the disclosure provide a structure that provides increased drain-source breakdown voltage for transistor devices at advanced technology nodes, e.g., 14 nanometers and beyond. The structure is advantageous for use with, for example, LDMOS FETs such as used for microwave or RF power amplifiers. The structure may include a gate structure between a first doping region, e.g., a source region, and a second doping region, e.g., a drain region, over a substrate. A trench isolation is partially under the gate structure and between the gate structure and the second doping region (source). A first well is under and adjacent the first doping region (source); and a second well is under and adjacent the second doping region (drain). The structure, in contrast to conventional LDMOS FETs, also includes a counter doping region abutting and between the first well and the second well, the counter doping region being directly underneath the gate structure. The counter doping region includes both n-type and p-type dopants, and provides a mechanism to increase drain-source breakdown voltage in a non-complex manner and without increasing the footprint of the device.

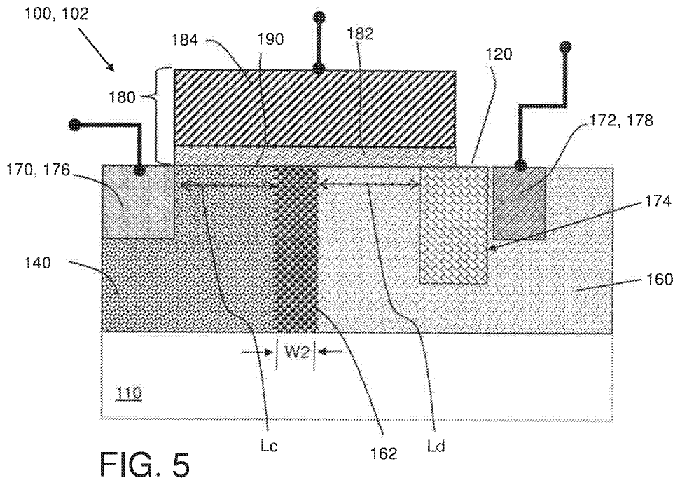

Embodiments of the disclosure will be described relative to a structure 100 (FIG. 5) in the form of an LDMOS FET 102. It will be appreciated, however, that the teachings herein may be applicable to other types of transistor devices, all of which are considered within the scope of the disclosure.

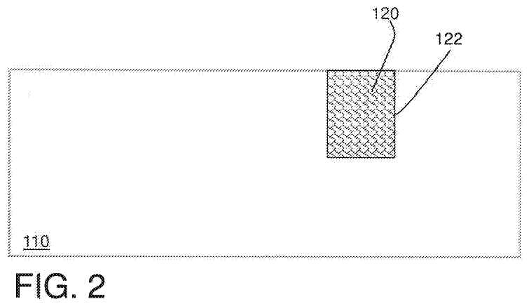

FIGS. 2-5 show cross-sections of a method of forming a structure 100 (FIG. 5) and an LDMOS FET 102 (FIG. 5), according to embodiments of the disclosure.

FIG. 2 shows a cross-sectional view of forming a trench isolation 120 in a semiconductor substrate 110. Semiconductor substrate 110 may include but is not limited to silicon, germanium, silicon germanium, silicon carbide, and those consisting essentially of one or more III-V compound semiconductors having a composition defined by the formula Al_{X1}Ga_{X2}In_{X3}As_{Y1}P_{Y2}N_{Y3}Sb_{Y4}, where X1, X2, X3, Y1, Y2, Y3, and Y4 represent relative proportions, each greater than or equal to zero and X1+X2+X3+Y1+Y2+Y3+Y4=1 (1 being the total relative mole quantity). Other suitable substrates include II-VI compound semiconductors having a composition Zn_{A1}Cd_{A2}Se_{B1}Te_{B2}, where A1, A2, B1, and B2 are relative proportions each greater than or equal to zero and A1+A2+B1+B2=1 (1 being a total mole quantity). Furthermore, a portion or entire semiconductor substrate may be strained. In one embodiment, semiconductor substrate 110 may include a p-type semiconductor substrate, i.e., including p-type dopant therein (e.g., with a dopant concentration of 1E15).

Doping is a process of introducing impurities (dopants) into the semiconductor substrate, or elements formed on the semiconductor substrate, and is often performed with a mask (or previously-formed, elements in place) so that only certain areas of the substrate will be doped. For example, as will be described, doping is used to form a source region and a drain region of a field effect transistor (FET). An ion implanter is typically employed for the actual implantation. An inert carrier gas such as nitrogen is usually used to bring in the impurity source (dopant). However, in-situ formation of dopant containing semiconductor may also be employed, e.g., deposition and/or epitaxy. Dopants may be n-type or p-type. N-type is an element introduced to a semiconductor to generate free electrons (by “donating” electrons to the semiconductor), and must have one more valance electron than the semiconductor. N-type dopants in silicon (Si) may include but are not limited to: phosphorous (P), arsenic (As), antimony (Sb). P-type is an element introduced to a semiconductor to generate free holes (by “accepting” electrons from the semiconductor atom and “releasing” holes at the same time), and acceptor atom must have one valence electron less than the host semiconductor. P-type dopants may include but are not limited to: boron (B), indium (In) and gallium (Ga).

Trench isolation 120 may be formed in semiconductor substrate 110 in any now known or later developed manner. Generally, a trench 122 is etched into semiconductor substrate 110 and filled with an insulating material. Typically, trench isolations, sometimes referred to as shallow trench isolations (STI), are used to isolate one region of the substrate from an adjacent region of the substrate. In accordance with embodiments of the disclosure, however, trench isolation 120 is within a final device to elongate a channel length of the device. Each trench isolation 120 may be formed of any currently-known or later developed substance for providing electrical insulation, and as examples may include: silicon nitride (Si₃N₄), silicon oxide (SiO₂), fluorinated SiO₂ (FSG), hydrogenated silicon oxycarbide (SiCOH), porous SiCOH, boro-phospho-silicate glass (BPSG), silsesquioxanes, carbon (C) doped oxides (i.e., organosilicates) that include atoms of silicon (Si), carbon (C), oxygen (O), and/or hydrogen (H), thermosetting polyarylene ethers, a spin-on silicon-carbon containing polymer material, near frictionless carbon (NFC), or layers thereof. In one embodiment, trench isolation 120 includes silicon oxide.

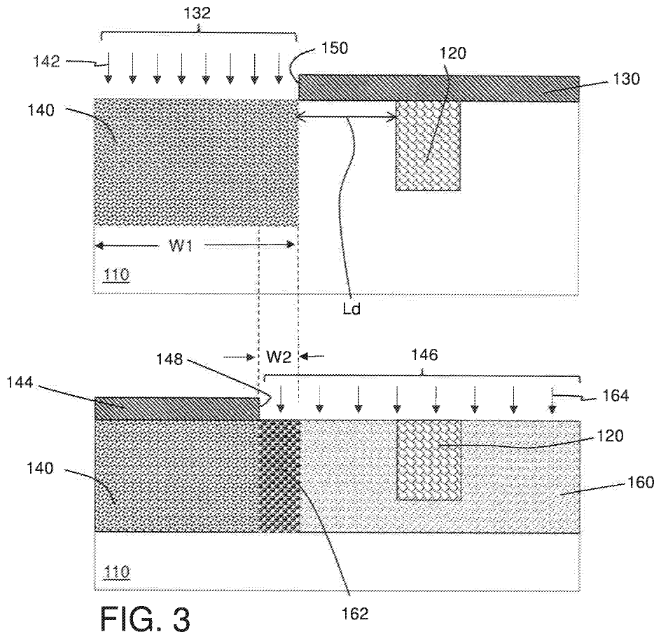

FIG. 3 shows a cross-sectional view of numerous steps of the method superimposed over one another to illustrate the overlap of two well forming steps to create a counter doping region. The upper part of FIG. 3 shows a cross-sectional view of a first step of forming a first mask 130 over semiconductor substrate 110. The term “mask” may be given to a layer of material which is applied over an underlying layer of material, and patterned to have openings, so that the underlying layer can be processed where there are openings. After processing the underlying layer, the mask may be removed. Common masking materials are photoresist (resist) and nitride. Nitride is usually considered to be a “hard mask.” Mask may include a developable organic planarization layer (OPL) on the layer to be etched, a developable anti-reflective coating (ARC) layer on the developable OPL, and a photoresist mask layer on the developable ARC layer. As illustrated, first mask 130 exposes a first region 132 to a first side (left side in example shown) of, and distanced from, trench isolation 120. The distance from trench isolation 120 can be selected to achieve a desired drain extension length (Ld).

The upper part of FIG. 3 also shows using first mask 130 for forming a first well 140 in semiconductor substrate 110 in first region 132. First well 140 may be formed using any now known or later developed doping method, e.g., ion implantation 142. First well 140 is distanced from trench isolation 120 by drain extension length Ld, i.e., it does not abut trench isolation 120. In one embodiment, first well 140 is a p-type well. Since first well 140 is doped p-type in a p-type semiconductor substrate 110, first well 140 has a higher p-type dopant concentration compared to p-type semiconductor substrate 110. First well 140 may extend to any depth appropriate for the type of device being formed, and may have any appropriate first dopant concentration.

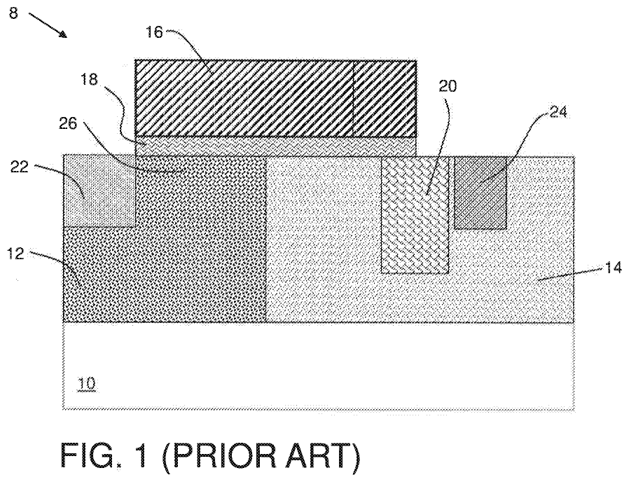

As shown in the cross-section in the lower part of FIG. 3, after first well 140 is formed, first mask 130 is removed, e.g., using ashing process, and a second mask 144 is formed over semiconductor substrate 110. Second mask 144 may be made of the same material and in the same manner as first mask 130. However, in contrast to conventional processing that align edges of masks to create abutting wells 12, 14 (FIG. 1), second mask 144 exposes a second region 146 including a portion of a width W1 of first well 140. That is, second mask 144 has an edge 148 (lower part FIG. 3) that is not aligned with the former location of an edge 150 of first mask 130 (upper part of FIG. 3). Consequently, mask 144 exposes a portion of first well 140. The portion of first well 140 may have a width W2, i.e., W2<W1. The lower part of FIG. 3 also shows a cross-section depicting a process of forming a second well 160 in semiconductor substrate 110 in second region 146 and a counter doping region 162 in the portion of the width of first well 140 exposed by second mask 144. Second well 160 and counter doping region 162 may be formed using any now known or later developed doping method, e.g., ion implantation 162. The doping in this step uses a different dopant than used to create first well 140 such that second well 160 includes the opposite dopant than first well 140, and counter doping region 162 includes both n-type dopants and p-type dopants. That is, first well 140 is doped with a first type dopant and second well 160 is doped with the other, second type dopant, and counter doping region 162 is doped with both dopants. In one non-limiting example, first well 140 may include a p-type dopant to create a p-well 140, and second well 160 may include an n-type dopant to create an n-well 160, and counter doping region 162 may include both n-type dopants and p-type dopants. The dopant concentrations of each well 140, 160 may vary depending on the type of device desired. In any event, a first dopant concentration exists in first well 140, a second dopant concentration exists in second well 160, and counter doping region 164 includes the first dopant concentration and the second dopant concentration.

Second well 160 may extend beside each side and under trench isolation 120. Second well 160 may extend to any depth appropriate for the type of device being formed, and may have any appropriate second dopant concentration. Counter doping region 162 will extend to the depth of the least deep well 140, 160. As illustrated, counter doping region 162 is spaced from trench isolation 120, i.e., by drain extension length Ld as defined by first mask 130. In one non-limiting example, at a 14 nanometer technology node, Ld may be between 0.2 and 0.4 micrometers.

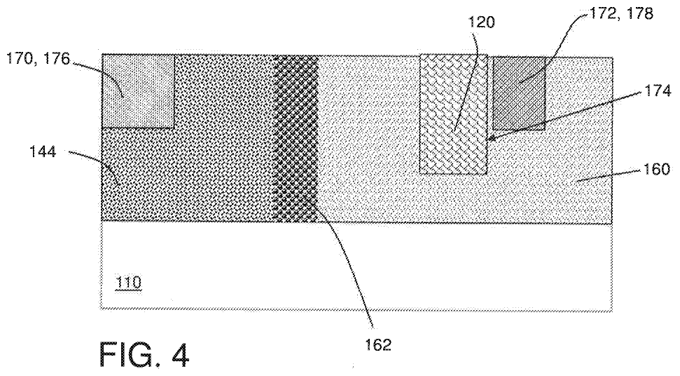

Referring to the cross-sectional view of FIG. 4, the method may include removing second mask 144, e.g., using an ashing process. FIG. 4 also shows forming a first doping region 170 in first well 140 and a second doping region 172 in second well 160 on an opposite side 174 of trench isolation 120 from first well 140. In one example, first doping region 170 may include an n-type dopant to create a source region 176, and second doping region 172 may include an n-type dopant to create a drain region 178. First doping region 170 forms source region 176, and second doping region 172 forms drain region 178. Doping regions 170, 172 may be formed using any now known or later developed doping process, e.g., using masks (not shown) to direct the doping. Any necessary anneals may be carried out to drive in the dopants.

FIG. 5 shows a cross-sectional view of forming a gate structure 180 between first doping region 170 and second doping region 172 and over semiconductor substrate 110. Gate structure 180 may include any now known or later developed material and/or structures for forming a transistor gate. For example, gate structure 180 may include a gate dielectric 182 over semiconductor substrate 110, and a gate conductor 184 over gate dielectric 182. Gate dielectric 182 may include but is not limited to: hafnium silicate (HfSiO), hafnium oxide (HfO₂), zirconium silicate (ZrSiOₓ), zirconium oxide (ZrO₂), silicon oxide (SiO₂), silicon nitride (Si₃N₄), silicon oxynitride (SiON), high-k material or any combination of these materials. Gate conductor 184 may include any now known or later developed gate conductor such as copper (Cu). A gate cap (not shown) of, for example, a nitride, may also be formed over gate conductor 184. Any necessary work function metal (not shown) may also be provided between gate dielectric 182 and gate conductor 184. Gate structure 180 may be formed using any now known or later developed techniques, e.g., deposition of material and patterning, replacement metal gate (RMG) processing, etc. As illustrated, when gate structure 180 is complete, trench isolation 120 is partially under gate structure 180 and is between gate structure 180 and second doping region 172, e.g., drain region 178. Gate structure 180 may extend over trench isolation 120.

FIG. 5 also shows structure 100 that may be used as an LDMOS FET 102. Structure 100 includes gate structure 180 between first doping region 170 and second doping region 172 over substrate 110. As noted, first doping region 170 may include an n-type dopant to create a source region 176, and second doping region 172 may include an n-type dopant to create a drain region 178. Trench isolation 120 may be partially under gate structure 180 and also between gate structure 180 and second doping region 172, e.g., drain region 178. First p-well 140 is under and adjacent first doping region 170, i.e., source region 176, and second n-well 160 is under and adjacent the second doping region 172, i.e., drain region 178. Second n-well 160 may extend about trench isolation 120. Structure 100 and LDMOS FET 102, in contrast to conventional structures, also includes counter doping region 162 abutting and between first p-well 140 and second n-well 160. Counter doping region 162 is directly underneath gate structure 180 such that it is below a channel 190 formed below gate structure 180 in semiconductor substrate 110. Counter doping region 162 is also spaced from trench isolation 120, i.e., by drain extension length Ld. Counter doping region 162 is also spaced from first doping region 170 to define a channel length Lc for the device. In one non-limiting example, at a 14 nanometer technology node, Lc may be higher than 0.2 micrometers.

Counter doping region 162 includes both n-type dopants and p-type dopants. As noted, in one embodiment, semiconductor substrate 110 may include a p-type dopant, the first dopant in first well 140 may include an n-type dopant, and the second dopant in second well 160 may include a p-type dopant. A first dopant concentration may be in first p-well 140, a second dopant concentration may be in second n-well 160, and counter doping region 162 may include the first dopant concentration and the second dopant concentration.

With counter doping region 162 including both n-type dopants and p-type dopants, it creates a more gradient junction than current structures. Consequently, structure 100 and LDMOS FET 102 can sustain higher drain-source breakdown voltages (BVdss), compared to conventional devices. As shown in FIG. 3, counter doping region 162 width W2 can be selected to tailor the drain-source breakdown voltage by controlling the placement of edge 150 of first mask 130, and more notably, edge 148 of second mask 144. Width W2 of counter doping region 162 can be selected to be between, for example, 25 nanometers and 200 nanometers, depending on the amount of increase in drain-source breakdown voltage desired. In one non-limiting example, width W2 may be 100 nanometers. It is noted that this extent of width W2 between wells 140, 160 is purposefully generated and is not possible by accidental or coincidental overlap of wells 140, 160, i.e., at the 14 nm and beyond technology node. The following table illustrates a non-limiting example of how width W2 of counter doping region 162 can be selected to improve a number of noted parameters:

| Counter doping | Vtsat | Idsat | Idoff | BVdss |
|---|---|---|---|---|
| region width (nm) | (V) | (uA/um) | (nA/um) | (V) |
| 0 | 0.236 | 669 | 0.044 | 8.6 |
| 25 | 0.231 | 682 | 0.027 | 8.77 |
| 50 | 0.223 | 713 | 0.035 | 8.96 |
| 75 | 0.212 | 730 | 0.368 | 9.15 |
| 100 | 0.201 | 757 | 0.034 | 9.46 |

In the example shown in the table, drain-source breakdown voltage (BVdss) can be increased anywhere from 8.6V to 9.5V, depending on width W2 of counter doping region 162. Counter doping region 162 also can improve saturation current (Idsat) without leakage degradation. In one non-limiting example, saturation current (Idsat) was increased from 669 to 757 micro-Amperes per micrometer, depending on the width W2 of counter doping region 162. Additional increases may be possible with widening of counter doping region 162 from 100 nanometers to 200 nanometers. It is noted that while counter doping region 162 provides the above advantages, it does not increase device footprint.

The method as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. “Optional” or “optionally” means that the subsequently described event or circumstance may or may not occur, and that the description includes instances where the event occurs and instances where it does not.

Approximating language, as used herein throughout the specification and claims, may be applied to modify any quantitative representation that could permissibly vary without resulting in a change in the basic function to which it is related. Accordingly, a value modified by a term or terms, such as “about”, “approximately” and “substantially”, are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise. “Approximately” as applied to a particular value of a range applies to both values, and unless otherwise dependent on the precision of the instrument measuring the value, may indicate +/−10% of the stated value(s).

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description, but is not intended to be exhaustive or limited to the disclosure in the form disclosed. Many modifications and variations will be apparent to those of ordinary skill in the art without departing from the scope and spirit of the disclosure. The embodiment was chosen and described in order to best explain the principles of the disclosure and the practical application, and to enable others of ordinary skill in the art to understand the disclosure for various embodiments with various modifications as are suited to the particular use contemplated.

1. A structure comprising:
a gate structure between a first doping region and a second doping region over a substrate;
a trench isolation partially under the gate structure and between the gate structure and the second doping region;
a first well under and adjacent the first doping region;
a second well under and adjacent the second doping region; and
a counter doping region abutting and between the first well and the second well, the counter doping region directly underneath the gate structure.

2. The structure of claim 1, wherein the counter doping region includes both n-type dopants and p-type dopants.

3. The structure of claim 1, wherein the counter doping region has a width between 25 nanometers and 200 nanometers.

4. The structure of claim 1, further comprising a first dopant concentration in the first well, a second dopant concentration in the second well, and wherein the counter doping region includes the first dopant concentration and the second dopant concentration.

5. The structure of claim 4, wherein the substrate includes a semiconductor substrate including a p-type dopant, the first dopant includes an n-type dopant, and the second dopant includes a p-type dopant.

6. The structure of claim 1, wherein the first doping region forms a source region, and the second doping region forms a drain region.

7. The structure of claim 1, wherein the counter doping region is spaced from the trench isolation.

8. The structure of claim 1, wherein the structure includes a laterally diffused metal-oxide semiconductor (LDMOS) device.

9. A laterally diffused metal-oxide semiconductor (LDMOS) field effect transistor (FET), comprising:
a gate structure between a source region and a drain region over a p-type semiconductor substrate;
a trench isolation partially under the gate structure and between the gate structure and the drain region;
a p-well under and adjacent the source region;
an n-well under and adjacent the drain region; and
a counter doping region abutting and between the p-well and the n-well, the counter doping region directly underneath the gate structure.

10. The LDMOS FET of claim 9, wherein the counter doping region includes both n-type dopants and p-type dopants.

11. The LDMOS FET of claim 9, wherein the counter doping region has a width between 25 nanometers and 200 nanometers.

12. The LDMOS FET of claim 9, further comprising a p-type dopant concentration in the p-well and an n-type dopant concentration in the n-well, wherein the counter doping region includes the p-type dopant concentration and the n-type dopant concentration.

13. The LDMOS FET of claim 9, wherein the counter doping region is spaced from the trench isolation.

14-20. (canceled)

21. The structure of claim 1, wherein a horizontal width of the first well between the first doping region and the counter doping region is greater than a width of the counter doping region between the first well and the second well.

22. The structure of claim 4, wherein the substrate includes a semiconductor substrate including an n-type dopant, the first dopant includes a p-type dopant, and the second dopant includes an n-type dopant.

23. The structure of claim 7, wherein the counter doping region is spaced between approximately 0.2 and approximately 0.4 micrometers from the trench isolation.

24. The LDMOS FET of claim 9, wherein a horizontal width of the p-well between the source region and the counter doping region is greater than a width of the counter doping region between the p-well and the n-well.

25. The LDMOS FET of claim 13, wherein the counter doping region is spaced between approximately 0.2 and approximately 0.4 micrometers from the trench isolation.
